(19) United States
(12) Patent Application Publication
(10) Pub. No.: US 2010/0157545 A1
(43) Pub. Date: Jun. 24, 2010

(54) INTERFERENCE SHIELDED ELECTRONICS MODULE AND METHOD FOR PROVIDING THE SAME

(75) Inventors: Kaija Lehtimaki, Lohja (FI); Greta Maakannas, Helsinki (FI); Mikko Heikonen, Espoo (FI); Kimmo Seppala, Espoo (FI)

Correspondence Address: BROOKS KUSHMAN P.C., 1000 TOWN CENTER, TWENTY-SECOND FLOOR, SOUTHFIELD, MI, 48075, US

(73) Assignee: ELCOTEQ SE, Luxembourg (LU)

(21) Appl. No.: 12/601,716

(22) PCT Filed: May 26, 2008
(86) PCT No.: PCT/FI08/00059

§ 371 Date: Jan. 13, 2010

(30) Foreign Application Priority Data
May 25, 2007 (FI) 20070415

(51) Int. Cl. H05K 7/00; B29C 65/70; H05K 9/00

(52) U.S. Cl. 361/728; 264/272.11; 361/818

(57) ABSTRACT

An interference shielded, for example a RFI and/or EMI shielded, for an electronics module which forms a contact with at least one edge zone of a circuit board, is provided. The contact functions in the electronics module as a ground. The circuit board includes an outermost electrically conductive layer providing the interference shield of the electronics module; at least one circuit card layer unit comprising electronics components and a wiring pattern embedded into a filling material of the circuit board layer; and encapsulating activation material layer. The activation material layer is advantageously a substrate layer or a resin layer, and which overlays above the topmost circuit board layer, and which is arranged into a space between the outermost layer and topmost circuit board layer to be therein conformingly against the inner surface of the outermost layer for isolating the electronic components and the wiring pattern from outermost layer.

The present invention relates interference shielded, for example a RFI (RFI, Radio Frequency Interference) and/or EMI shielded (EMI, Electromagnetic Interference), electronics module, such as a circuit board unit (10) or a printed circuit or a corresponding electronics module, to interference-shielded electronics modules, especially for protecting electronics modules, such as circuit boards or printed circuits or corresponding electronics modules, against EM interferences (EM, “Electromagnetic Interference”) and/or RF interferences (RF, “Radio Frequency Interference”), in other words the present invention relates to solutions for shielding electronics modules against RFI and/or EM interferences.

More precisely, the present invention relates to interference-shielded electronics module, for example to a RFI shielded and/or EMI shielded circuit board, according to the preamble of the independent claim 1. The present invention relates also to method for providing the interference-shielded electronics module, for example the RFI shielded and/or the EMI shielded circuit board, according to the preamble of the independent claim 11.

According to the prior art, it is ordinary that a grounding of the electronics module to be RF and/or EM interference-shielding is carried out by forming a conductive contact between the outermost surrounding shield layer and the circuit board layer, which functions as a grounding layer. The grounding layer is provided with grounding pads and the contact extends typically through an isolating substrate layer, in which each of the circuit board layer are embedded, through an opening or a cavity that is called a via or a microvia.

In the publication JP2005276980, which represents the closest prior art, has been presented a method to produce the module provided with circuit components and with wiring patterns and with an external shielding. According to the publication a sufficient shielding effect is provided as such against higher frequencies from the point of view of a size, of a height and of a weight of the electrical apparatus. Further the publication states that the shielding improves a shielding of the module that is provided with internal electronic components. In the method presented in the publication, the module, which is provided with the internal electronic components and with several internal circuit boards, is divided into separate circuit boards by cuttings. A first metal layer, which is a chemical copper coating, a second metal layer, which is an electrolytic copper coating, and the third metal layer, the purpose of which is to prevent the oxidizing of the copper of the second metal layer, is formed onto the surface and onto outer sides of an insulator of each separate circuit board. The most essential problems and weaknesses of the solution, which is in accordance with the publication, are that the shielding is as such a multi-layered arrangement and the same is made by different coating techniques, hence the manufacturing process is technically complex and slow and requires considerable amount of line space.

In the publication JP2006286915 it has been proposed that components, which are installed in the circuit board having a grounding layer, are closed inside isolating resin, are shielded against interferences by means of a conductive resin layer, which contains metal flakes, is spread over the isolating resin layer, in which cage the conductive resin layer can function as the interference shield.

An object of the present invention is to eliminate or to reduce at least essentially those problems and weaknesses, which are related to the solution, which is in accordance with the prior 3rt. A second object of the present invention is to accomplish a new and inventive solution to carry out an interference shielding, which solution would be suitable for example for the interference shield of the circuit board of mobile communications equipment. A third object of the present invention is to simplify the carrying out of the interference shielding of circuit boards on the assembly line and to accomplish a new and inventive method for carrying out interference shielding, for example for carrying out the interference shielding for the circuit board of the mobile communications equipment.

The objects of the present invention can be reached out in general by means of the interference-shielded electronics module mentioned in the beginning of the description above according to the characterizing part of the independent claim 1.

The objects of the present invention can be reached out also in general by means of the method mentioned in the beginning of the description above according to the characterizing part of the independent claim 9.

The interference-shielded circuit board that is used in the mobile station can be mentioned as an advantageous application area of the present invention.

Concerning other special characteristics of the invention, reference is made to the dependent claims of the enclosed set of claims.

About the advantages of the invention, one can mention as follows. By means of the present invention the number of the stages needed on the assembly line can be reduced; it is possible to accomplish interference-shielded structure, where both the structure height and the surface area of the circuit board are essentially smaller than the structure height of the interference-shielded circuit board and the surface area of the module that could be accomplished by the prior art; there is achieved a contact, the firmness of which is better than the firmness that is possible to achieve by the grounding technique adapting grounding pads; and production tolerances are essentially larger than in the grounding technique adapting the traditional grounding pads.

The invention is described in the following only by way of examples by means advantageous embodiment thereof referring to enclosed patent drawing, where

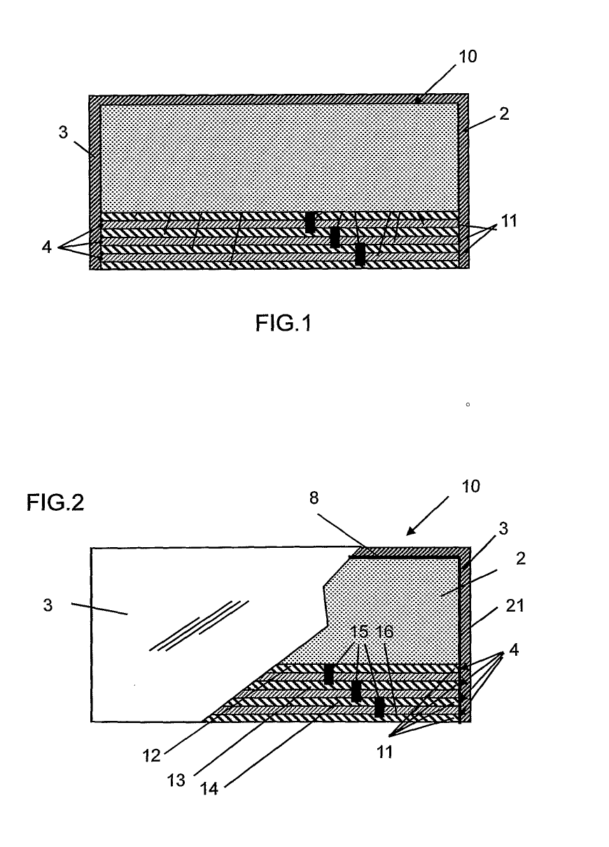

FIG. 1 presents a crosscut side view of a circuit board unit according to a first preferred embodiment of the present invention, which unit, is covered with an outermost layer, which is preferably a single layered metal layer and which provides an interference shielding, when brought into a direct conductive contact with the edge zone of a circuit board layer, which contact functions hence as the means of grounding,

FIG. 2 presents a partial crosscut side view of the interference-shielded circuit board, which is in accordance with a second preferred embodiment of the present invention,

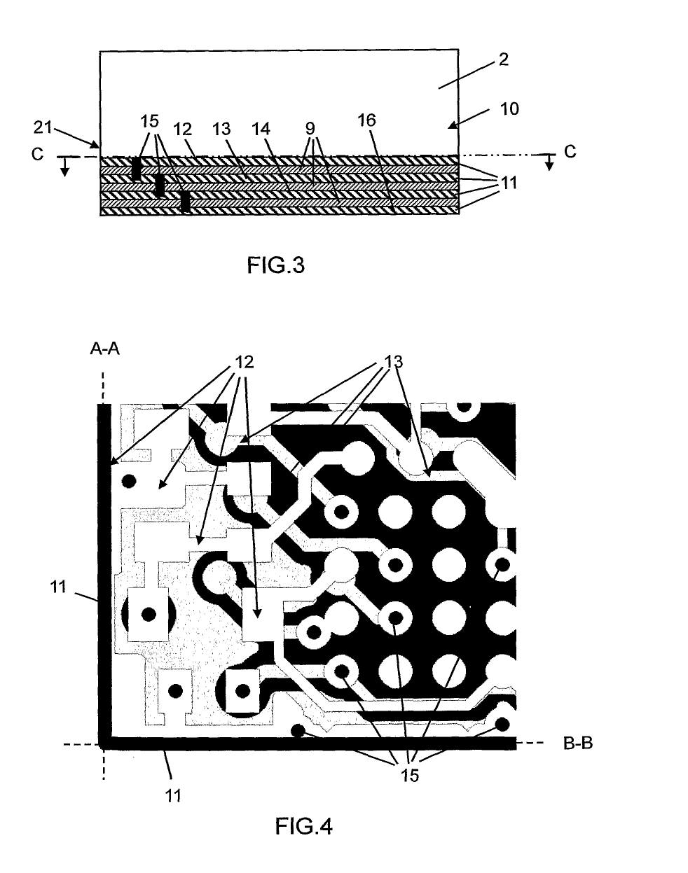

FIG. 3 presents the crosscut side view of a non-shielded circuit board unit of FIG. 1 but without the outermost surrounding layer or of FIG. 7, which non-shielded unit is covered by conforming and encapsulating material layer and where at least one edge zone of at least one circuit board layer functions as a means of grounding and is exposed at side edge of the circuit board unit,

FIG. 4 presents a corner of the circuit board unit in the panel of FIG. 2, which unit is intended to be singulated according to the present invention along the cutting lines A-A and B-B, as seen from above in the plane C-C of FIG. 3, i.e. before the encapsulating layer is applied on top of the uppermost circuit board layer of the circuit board layers each comprising embedded wiring pattern and electrical components. For the sake clarity the circuit boards of the pile of the circuit boards that are one above the other are illustrated as transparent.

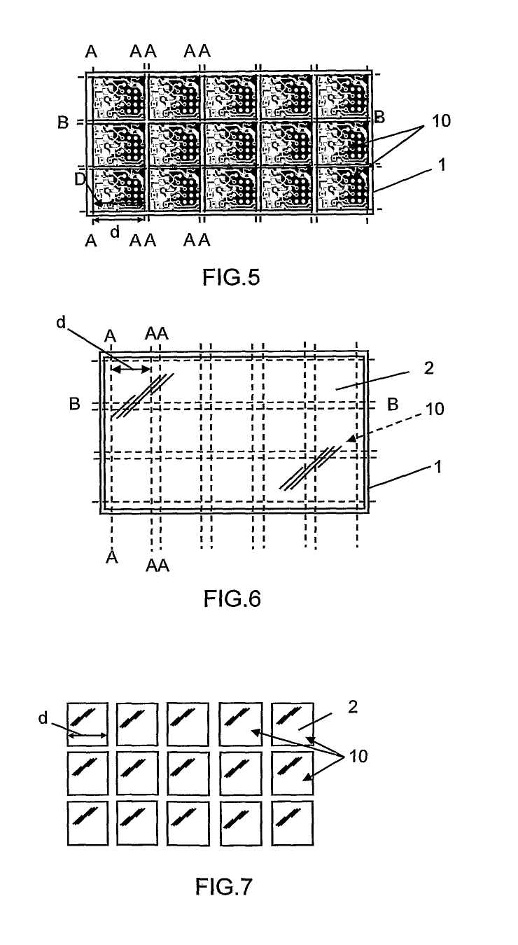

FIG. 5 presents, as seen from above, the panel with fifteen electronics modules, such as the circuit board unit, to be separated along cutting or depanelisation lines,

FIG. 6 presents, as seen from above, the panel of the electronics modules, such as the panel of the circuit board unit, which is covered with the encapsulating activation layer, such the overmoulded resin or another mouldable conforming and isolating material, and which is intended to be singulated according along the cutting lines,

FIG. 7 presents, as seen from above, the circuit boards that have been separated from the panel along the cutting lines,

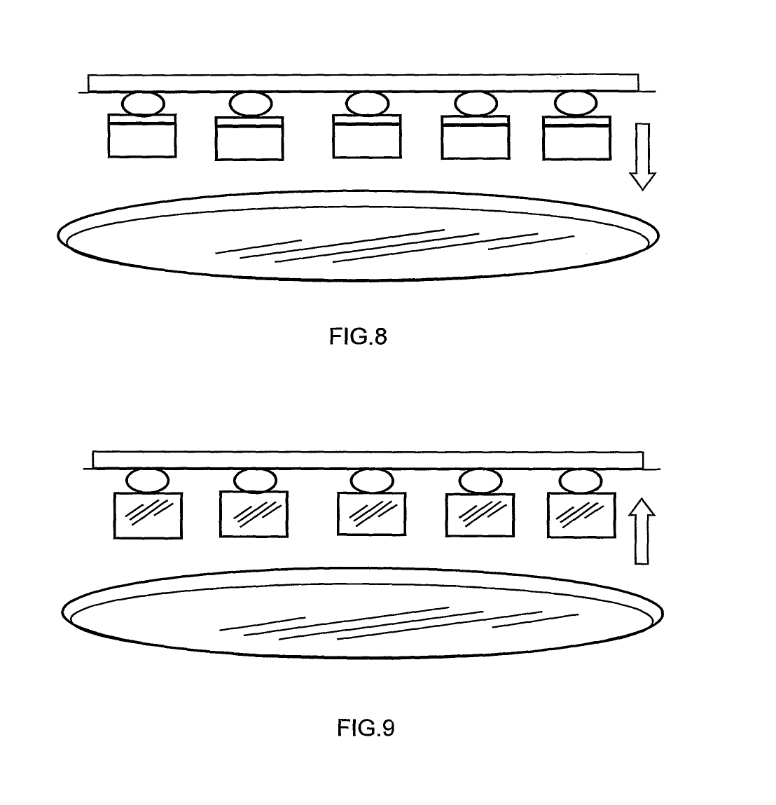

FIG. 8 presents a transfer of the circuit board units with the help of the vacuum from the bottom side above a basing comprising paste, paint, or a corresponding material, and a dipping of the circuit board units into the basin in which cage the material height in the basin is adjusted, and

FIG. 9 presents circuit board units after the dipping, whereby the same are ready for drying.

Reference is made to FIG. 1 that presents a crosscut side view of the EMI/RFI shielded circuit board unit 1 according to a first preferred embodiment. According to the embodiment of FIG. 1 the crosscut form of the circuit board 10 is advantageously a parallelogram, most advantageously the rectangular parallelogram.

The electronics module 10 of FIG. 1 comprises an electronics part, which comprises one or several multi-layered circuit board units, the layers 12, 13, 14, 16 of which are locating one on the other. The electronics part of the circuit board unit is covered by an encapsulation activation layer 2, which of insulating material and which is typically overmoulded on the topmost layer 12 of the multi-layered circuit board unit 12, 13, 14, 16, 17. Typical material of the over moulded layer is resin or another mouldable insulating material. As the outermost layer of the electronics module 10 is applied a single layered surrounding shield layer 3 that provides the interference shield, such as the EMI/RFI shield. The construction of the circuit board unit 10 including multi-layered electronics part comprises:
Either a single-sided core layer 17 or a double-sided core layer, which is typically made of fire resistance class fibreboard, preferably of class 5, and
Circuit components layers 12, 13, 14, in which the wiring pattern is embedded into a filling material that is preferably copper.

In the connection of the embodiment of FIG. 1, there is reason to emphasize that the electronics part 12, 17 may be composed of one or several single-layered circuit board units 12, 17 that are locating side by side in plane. The insulating activation layer 2 covers the topmost layer 12 of the single-layered circuit board unit. Preferred material of the over moulded layer are resin and other mouldable insulting materials. As the outermost layer of the electronics module is applied the surrounding shield layer 3 that provides the EMI/RFI shield. The construction of the circuit board unit 10 including the single-layered electronics part comprises
Either a single-sided core layer or a double-sided core layer 17, which is typically made of fire resistance class fibre board, preferably of class 5, and
Circuit components layer 12, in which a wiring pattern is embedded into a filling material that is preferably copper.

The covering single-layered shield layer 3 is in the first embodiment, according to FIG. 1, advantageously a metal layer, preferably of copper, that accomplishes around the circuit board unit 10 the shield against Electromagnetic and/or Radio Frequency interferences and against this kind of radiation, hence there is provided a two directional interference shield that is advantageously the RFI and/or EMI interference shield. The edge zone 11 of the circuit board layers 12, 13, 14 functions as the means of grounding in the circuit board unit when being in the conductive contact 4 with the edge zones of the circuit board layers preferably with the edging filling material of circuit components layers 12, 14, 15. It is preferred that the individual circuit components layers are connected to each other with vias 15 and/or microvias. Hence the edge zone functions at the side edge of the circuit board unit as a contact means for providing the grounding. In the embodiments of FIG. 1, the filling of the circuit component s layers 12, 13, 14 material can be for example copper that functions as the grounding means and provide the conductive conduct with surrounding shield layer.

Reference is made to FIG. 2 that presents a crosscut side view of the EMI/RFI shielded circuit board unit 1 according to a second preferred embodiment. According to the embodiment of FIG. 2 the crosscut form of the circuit board 10 is advantageously a parallelogram, most advantageously the rectangular parallelogram.

The covering single-layered shield layer 3 is in the second embodiment, according to FIG. 2, advantageously a metal layer, preferably of copper, that accomplishes around the circuit board unit 10 the shield against Electromagnetic and/or Radio Frequency interferences and against this kind of radiation, hence there is provided a two directional interference shield that is advantageously the RFI and/or EMI interference shield. The edge zone 11 of the circuit board layers 12, 13, 14 functions as the means of grounding in the circuit board unit when being in the conductive contact 4 with the edge zones of the circuit board layers preferably with the edging filling material of circuit components layers 12, 14, 15. It is preferred that the individual circuit components layers are connected to each other with vias 15 and/or microvias. Hence the edge zone functions at the side edge of the circuit board unit as a contact means for providing the grounding. In the embodiments of FIG. 2, the filling of the circuit component s layers 12, 13, 14 material can be for example copper that functions as the grounding means and provide the conductive conduct with surrounding shield layer.

The essential difference between the embodiments according to FIG. 1 and FIG. 2 is that
an additional adhering layer 8 is arranged onto the side surface of a non-shielded circuit module and under the surrounding shield layer 3, or
the outer side surface of the non-shielded circuit module is pre-treated chemically, or
the outer side surface of the non-shielded circuit module is pre-treated mechanically, preferably by grooving the outer side surface of the non-shielded circuit module.

By these measures attachment between the encapsulating layer 2 and the outermost conductive shield layer 3 is secured and certified.

The structure of the additional layer 8 pr the pre-treated surface of the non-shielded circuit board unit does not have to be entire whole. Hence the structure thereof can be holey or netlike, whereby an improved attachment is achieved between the shield layer 3 both with edge zones 11 of the circuit board layers 12, 13, 14 and with the outer surface of the encapsulating layer 2.

Reference is made to FIG. 3, which presents a crosscut of the non-shielded circuit board 10, which is cut apart from the panel (1, see FIG. 5) of circuit board modules 10 along the separation lines (A-A, B-B, see FIG. 5). The non-shielded circuit board is covered only by the encapsulating and conforming activation layer 2, a purpose of which is to isolate components from the interference shield layer (3, see FIG. 1 and FIG. 2) to be applied as the outermost surrounding onto the circuit board unit 10. The upper layer 14 of lower or bottom circuit board and the upper layers 13 of each of the internal or inner circuit boards as well as the top layer 12 the topmost circuit board are preferably made of copper or at least are composed of electronics circuit layer that are filled with copper, for utilizing the same layers as the means for the groundings and hence for utilizing the layers 12, 13, 14 as the grounding layers. The edges of the grounding layers 12, 13, 14 are exposed at the side edge of the circuit board 10 by the separation cutting of the panel, which is made along separation lines that runs along a centre line of the edging copper of the circuit board. In order to certify the fact that grounding metal, which is preferably copper is exposed by the separation cutting, each of the grounding layers 12, 13, 14 is edged by copper for providing an edge zone 11 by means of which the contact 4 with the outer coating layer or covering layer 3 is certified. The circuit board 10 is for example a multi-layered printed circuit board or a corresponding electronics component.

Reference is made to FIG. 4, which presents a corner of the electronics part of an individual and non-shielded circuit board unit 10 in the panel (1, see FIG. 5). The non-shielded circuit board is intended to be singulated or separated along the cutting lines A-A and B-B after the encapsulating activation layer 2 is applied on top of the uppermost circuit board layer 12 of the circuit board unit. For the sake clarity the topmost circuit board layer 12 is illustrated as transparent.

For maximizing and for certifying and for assisting the groundings of the layers 11, 12, 14 of the circuit board 10 by the conductive contacts 4 at the side edge 21 of the circuit board between each of the edge zones 11 of the circuit board layers and the conductive coating layer or the conductive covering shield layer 3,
the circuit boards 10 are singulated/separated from the panel 1 along the cutting/separation lines A-A, B-B before the conductive coating/covering shield layer 3 is applied on the pile of circuit boards, which are connected to each other by vias 15 or micro-vias,
the edge zones 11 as well as the spaces between the electronic components and wiring patterns/-s in each layer 12, 13, 14 of circuit board are filled by conductive metal, advantageously by filling copper, for covering the whole top area of the circuit board by the filling metal and edging metal.

Reference is made to FIG. 5, FIG. 6 and FIG. 7. In the pair of separation lines A-A; B-B, the separation lines that are overlapping with a circuit board 10 or with a row of circuit boards, a space d between the lines is smaller than a width D of the individual circuit board or the row of the circuit boards. It is advantageous that in each pair of the separation lines A-A, which is overlapping the row of the circuit boards, the space d between the lines is smaller than the width D of the individual circuit board or the row of the circuit boards.

Reference is made to FIG. 5, which presents a panel 1 that comprises 15 circuit boards 10, which is not interference-shielded. Cutting lines A-A and B-B of the panel used for separating individual circuit boards in a later process stage apart from each other, are illustrated by dash lines and dotted in FIG. 5.

Reference is made to FIG. 6, which presents the panel 1 that comprises 15 non-shielded circuit boards 10. The panel is covered by the conforming and encapsulating material layer 2 or of a substrate layer, which is preferably moulded in place, or which may be of any mouldable and isolating material. The separation lines A-A and B-B of individual circuit boards are illustrated in FIG. 6 like in FIG. 5 by dash lines and dotted lines.

FIG. 7 illustrates the covered circuit boards 10 separated from each other along the separation lines, A-A and B-B. The interference-shielded circuit board comprises the encapsulating material layer 2, wherein the pile of circuit board layers is embedded. The encapsulating material layer is moulded in place and covered by the interference shield accomplishing shield layer 3, whereby the shield layer covers at least a surface corresponding to the area required for the electronic components that are embedded in filling material of the topmost circuit board layer 12. The shield layer 3 causing the RFI/EMI shield accomplishes at a circumference of the electronics module a conductive contact 4 with edge zone 11 of each of the circuit board layers 12, 13, 14, in other words the surrounding shield layer is grounded separately with each of the circuit board layers of circuit boards unit and hence the contact 4 functions as the means of grounding.

Reference is made to FIG. 8 and FIG. 9 presenting phase by phase the process for providing the interference-shielded circuit boards.
FIG. 8 presents the transfer of the individual circuit boards 10 from the bottom sides of the singulated circuit board units by means of the vacuum nozzles above the basin 5, which contains conductive material that is for example paste, paint, ink or a corresponding, and the dipping of the circuit board units 10 in the direction of the arrow into the conductive paste or paint or ink, whereby level height of the material in the basin is controlled or adjusted.
FIG. 9 presents lifting of the individual circuit board units from the basin the circuit boards after the watering, in which case the same are covered by the material layer, which forms the contact 4 in the circuit board with edge zone 11 of the metal layer 12, 13, 14, which functions as the grounding layer, after which the circuit boards are ready for the drying. After the drying there is formed the coating layer or the covering layer 3 that makes the conductive contact with the edge zone 11 of the circuit board layer 12, 13, 14 for grounding the circuit board layer and for providing the interference-shielded electronics module.

The invention is described above only by means of an example thereof. As it is evident to any skilled in the art, this is not meant to limit the scope of the invention by any means, but several variations and alternative embodiments as well as equivalent modifications are possible within the inventive idea defined in by the accompanying claims, So the circuit boards that have been separated from the panel can also be covered by spreading a metallic coating, for example by as the coating layer or the covering layer that accomplishes the interference shield by sputtering, by painting, by spraying with steaming or by another such a metal coating method.

1. Interference shielded, for example a RFI and/or EMI shielded, electronics module, such as a circuit board unit or a printed circuit or a corresponding electronics module, which interference shield forms a contact with at least one edge zone of the circuit board layers of the circuit board, which contact functions in the electronics module as a means of grounding and which circuit board comprises
an outermost electrically conductive layer providing the interference shield of the electronics module,
at least one circuit card layer, unit comprising electronics components and a wiring pattern embedded into a filling material of the circuit board layer, and
encapsulating activation material layer, which is advantageously a substrate layer or a resin layer, and which overlays above the topmost circuit board layer, and which is arranged into a space between the outermost layer and topmost circuit board layer to be therein conformingly against the inner surface of the outermost layer for isolating the electronic components and the wiring pattern from outermost layer, whereby for providing the interference shield, there is a direct conductive contact at the side edge of the circuit board between the outermost layer and the edge zone of the circuit board layer providing the grounding, wherein the outermost shield layer is essentially a single-layered covering and an outermost surface layer of the circuit board unit.

2. Interference shielded electronics module according to claim 1, wherein the outermost shield layer is an RFI and or EMI shield that is an essentially uniform and a single-layered layer that covers the circuit board unit as the outermost layer at the top surface of the said unit and at each side surface of the said unit.

3. Interference shielded electronics module according to claim 1, wherein the outermost shield layer, which is applied as the outermost layer over the circuit board unit, is a metal coating of selective metal that is applied by a suitable metal coating method, such as for an example by dipping, by sputtering, by painting, by spraying, by steaming or by another corresponding way.

4. Interference shielded electronics module according to claim 3, wherein optionally
an additional layer is arranged between the outermost shield layer, or—the outer side edges or surfaces of the encapsulating layer and edge zones of the circuit board layers pre-treated chemically, or
the outer side edges or surfaces of the encapsulating layer and edge zones of the circuit board layers pre-treated mechanically, preferably by grooving.

5. Interference shielded electronics module according claim 4, wherein the structure of the additional layer or the pre-treated surface is uniform.

6. Interference shielded electronics module according to claim 4, wherein the structure of the adhesive layer is non-unitary, such as holey or netlike.

7. Interference shielded electronics module according to claim 1, wherein for maximizing and for certifying and for assisting the groundings of circuit board layer achieved by the conductive contacts between the edge zones of the circuit board layers and the coating/covering shield layer,
the circuit board layers are connected to each other by vias or microvias, and
the edge zones as well as the spaces between the electronic components and wiring patterns/-s are filled by conductive metal, advantageously by filling copper in each layer for covering the whole top area of the circuit board layer by the filling metal and edging metal.

8. Interference shielded electronics module according to claim 1, wherein the interference shield is an interference shield of communications equipment, such as for example the interference shield of the circuit board of the mobile station.

9. Method for providing an interference shielded electronics module, such as a RFI and/or EMI shielded circuit board unit or a printed circuit or a corresponding electronics module, the shielded module comprising:
at least one circuit card layer unit comprising electronics components and a wiring pattern embedded into a filling material of the circuit board layer, and
encapsulating activation material layer, which is advantageously a substrate layer or a resin layer, and which overlays above the topmost circuit board layer, and which is arranged into a space between the outermost layer and topmost circuit board layer to be therein conformingly against the inner surface of the outermost layer for isolating the electronic components and the wiring pattern from outermost layer, whereby there is a direct electrically conductive contact at the side edge of the circuit board unit between the shield layer and the edge zones of the circuit board layers to be grounded for accomplishing the interference shielded electronics module, preferably the EMI shielded and/or the RFI shielded electronics module, wherein the method comprises steps: a panel comprising several circuit board units is covered by an encapsulating layer; individual circuit boards are separated from the panel along separation lines of the circuit board units; and a surrounding shield layer is applied as the outermost layer, which forms an electrically conductive interference shield.

10. Method according to claim 9, wherein the outermost layer is applied as essentially uniformly and most advantageously as single-layered layer over upper most surface and the side surfaces of the circuit board unit for providing the interference shielded electronics module.

11. Method according to claim 9, wherein the circuit board units are separated from the panel along the separation lines that overlapping with a circuit board unit or a row of circuit board units.

12. Method according to claim 11, wherein the grounding means, advantageously the filling metal, most advantageously copper is exposed at the side edge of the circuit board unit by a separation cuttings of the circuit board units along the separation lines.

13. Method according to claim 9, wherein the interference shield is accomplished by applying on the non-shielded circuit board unit the outermost layer of electrically conductive material, which is advantageously a metal layer, and by bringing the outermost layer into the conductive contact with the edge zone of the circuit board layer to be grounded, which contact functions as the means of grounding at the side edge of the circuit board unit.

14. Method according to claim 9, wherein the circuit board units that are separated from the panel are dipped into a basin, which includes electrically conductive material, which is advantageously paste, paint, ink or a corresponding electrically conductive material, and that finally the circuit board is dried, whereby the surrounding shield layer generating the outermost surface is formed of material, which accomplishes the conductive contact with the edge zone of the circuit board layer.

15. Method according to claim 9, wherein the outermost surrounding layer accomplishing the shield layer, which is most advantageously a metallic coating, is applied on the top surface and on the side surfaces of the non-shielded electronics module by a suitable metallic coating method sputtering, such as by painting, by spraying, by steaming.

16. Method according to claim 9, wherein for securing the attachment of the shield layer, optionally
an additional adhering layer is arranged between the outermost shield layer, or
the outer side edges or surfaces of the encapsulating layer and edge zones of the circuit board layers pre-treated chemically, or—the outer side edges or surfaces of the encapsulating layer and edge zones of the circuit board layers pre-treated mechanically, preferably by grooving.

17. Method according to claim 9, wherein for maximizing and for certifying and for assisting the groundings of the layers of the circuit board unit by the conductive contacts at the side edge of the circuit board unit between each of the edge zones of the circuit board layers and the conductive shield layer,
the circuit boards are singulated/separated along the cutting lines from the panel before the conductive shield layer is applied on the non-shielded circuit board unit, the edge zones as well as the spaces between the electronic components and wiring patterns/-s are filled by conductive metal, advantageously by filling copper in each layer for covering the whole top area of the circuit board layer by the filling metal and edging metal, and
the individual circuit board units are dipped into a basin, which includes electrically conductive material, which is advantageously paste, paint, ink or a corresponding electrically conductive material, in which basin the height of the material is adjusted.
